(19) United States
(12) Patent Application Publication
(10) Pub. No.: US 2026/0225868 A1
(43) Pub. Date: Aug. 6, 2026

(54) TRANSPORT DEVICE, AND TRANSPORTED BODY

(71) Applicant: FUJI CORPORATION, Chiryu (JP)

(72) Inventors: Shigeyoshi INAGAKI, Yokkaichi-shi (JP); Hidemitsu HAMAI, Hekinan-shi (JP)

(73) Assignee: FUJI CORPORATION, Chiryu (JP)

(21) Appl. No.: 19/150,351

(22) PCT Filed: Feb. 10, 2023
(86) PCT No.: PCT/JP2023/004564

§ 371 Date: Jul. 23, 2025

(51) Int. Cl. B66F 9/06; B65H 19/12; B66F 9/075; G05D 1/667; G05D 107/70; H05K 13/00

(52) U.S. Cl. CPC B66F 9/063; B65H 19/12; B66F 9/0755; G05D 1/667; H05K 13/0084; B65H 2701/1942; G05D 2107/70

(57) ABSTRACT

A conveyance device including: a cart having a latching section; and a conveyed body configured to be placed on the cart so as to be slidable in a predetermined direction and be conveyed by movement of the cart, in which multiple latched sections to be latched by the latching section are formed in the conveyed body side by side in the predetermined direction, and the conveyed body is placed at a predetermined position on the cart by the latching section latching to a first latched section among the multiple latched sections, and the latching section latches to a latched section other than the first latched section among the multiple latched sections when the conveyed body deviates from the predetermined position.

### TECHNICAL FIELD

The present disclosure relates to a conveyance device including a cart and a conveyed body placed on the cart and conveyed.

### BACKGROUND ART

The following Patent Literature describes a conveyance device including a cart and a conveyed body placed on the cart and conveyed.

### CITATION LIST

### Patent Literature

Patent Literature 1: WO 2021/144866

### BRIEF SUMMARY

### Technical Problem

An object of the present description is to appropriately convey a conveyed body placed on a cart.

### Solution to Problem

In order to achieve the above object, the present description discloses a conveyance device including: a cart having a latching section; and a conveyed body configured to be placed on the cart so as to be slidable in a predetermined direction and be conveyed by movement of the cart, in which multiple latched sections to be latched by the latching section are formed in the conveyed body side by side in the predetermined direction, and the conveyed body is placed at a predetermined position on the cart by the latching section latched to a first latched section among the multiple latched sections, and the latching section latches to a latched section other than the first latched section among the multiple latched sections when the conveyed body deviates from the predetermined position.

In addition, the present description discloses a conveyed body configured to be placed on a cart so as to be slidable in a predetermined direction and be conveyed by movement of the cart, the conveyed body including: multiple latched sections to be latched by a latching section disposed on the cart, the multiple latched sections being formed in the conveyed body side by side in the predetermined direction, in which the conveyed body is placed at a predetermined position on the cart by the latching section latched to a first latched section among the multiple latched sections, and the latching section latches to a latched section other than the first latched section among the multiple latched sections when the conveyed body deviates from the predetermined position.

### Advantageous Effects

In the present description, the conveyed body is placed on the cart so as to be slidable in the predetermined direction. In addition, the multiple latched sections are formed in the conveyed body side by side in the predetermined direction. Then, the conveyed body is placed at the predetermined position on the cart by the latching section, which is disposed in the cart, latching to the first latched section among the multiple latched sections, and the latching section latches to the latched section other than the first latched section among the multiple latched sections when the conveyed body deviates from the predetermined position. Accordingly, for example, it is possible to prevent the conveyed body from falling, and it is possible to appropriately convey the conveyed body placed on the cart.

### BRIEF DESCRIPTION OF DRAWINGS

FIG. 1 is a perspective view showing a board work system.

FIG. 2 is a perspective view showing a mounting device and a feeder exchange device.

FIG. 3 is a perspective view showing a tape feeder.

FIG. 4 is a perspective view showing a storage rack.

FIG. 5 is a side view showing a feeder storage and an automatic conveyance cart.

FIG. 6 is a schematic view showing the board work system and a rack management device.

FIG. 7 is a view showing the storage rack placed on the automatic conveyance cart.

FIG. 8 is a view showing a lock mechanism.

FIG. 9 is a view showing the lock mechanism.

FIG. 10 is a view showing a lock mechanism in which a second latched section is not formed.

FIG. 11 is a perspective view showing the automatic conveyance cart.

FIG. 12 is a view showing the storage rack placed on the automatic conveyance cart.

### DESCRIPTION OF EMBODIMENTS

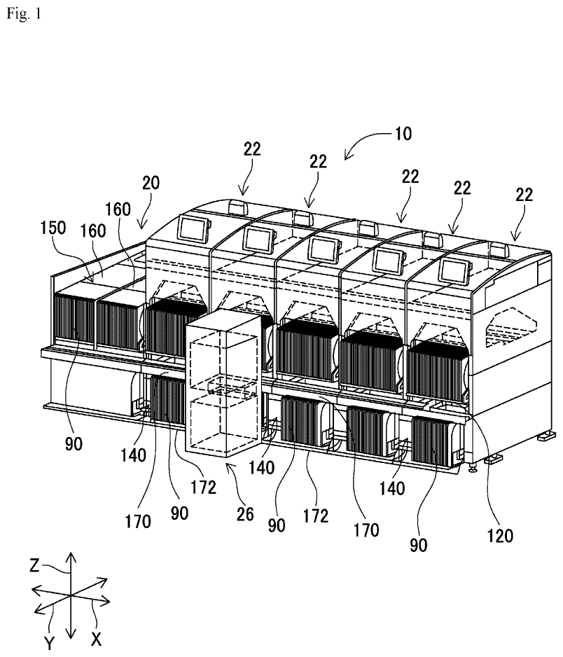

FIG. 1 shows board work system 10. Board work system 10 shown in FIG. 1 is a system for mounting an electronic component on a circuit board. Board work system 10 includes one feeder storage 20, five mounting devices 22, and one feeder exchange device 26. One feeder storage 20 and five mounting devices 22 are disposed in a row in a state in which one feeder storage 20 and five mounting devices 22 are adjacent in this order. Feeder exchange device 26 is disposed on a front side (front side in FIG. 1) of feeder storage 20 and mounting devices 22. In the following description, a direction in which feeder storage 20 and mounting devices 22 are arranged is referred to as an X direction, a horizontal direction perpendicular to the X direction is referred to as a Y direction, and a direction orthogonal to the X direction and the Y direction is referred to as a Z direction. In the X direction, a side on which feeder storage 20 is disposed is referred to as an upstream side, and a side on which mounting device 22 is disposed is referred to as a downstream side.

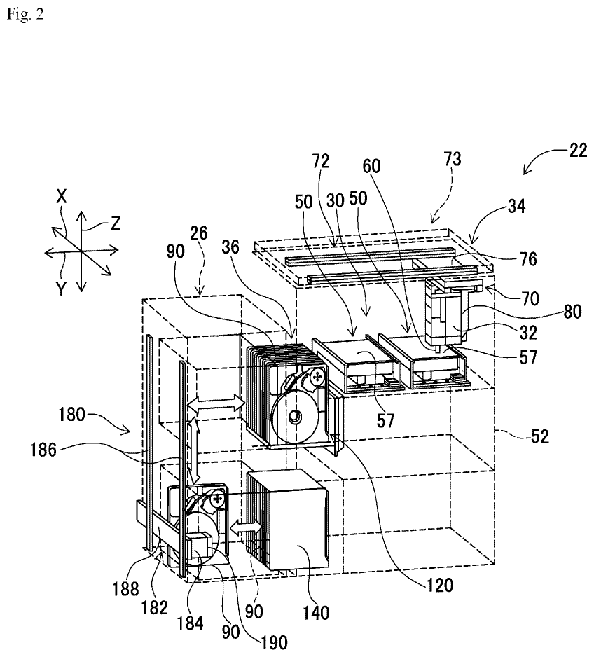

Five mounting devices 22 have substantially the same configuration as each other, and each of five mounting devices 22 includes conveyance device 30, mounting head 32, mounting head moving device (hereinafter, abbreviated as a “moving device” in some cases) 34, and supply device 36, as shown in FIG. 2.

Conveyance device 30 includes two conveyor devices 50. Two conveyor devices 50 are disposed on base 52 to extend parallel to each other and extend in the X direction. Each of two conveyor devices 50 conveys circuit board 57 supported by each of conveyor devices 50 in the X direction by an electromagnetic motor (not shown). In addition, each conveyor device 50 includes a board holding device (not shown), and fixedly holds circuit board 57 at a predetermined position.

Mounting head 32 mounts the electronic component on circuit board 57. Specifically, mounting head 32 includes suction nozzle 60 provided on a lower end surface thereof. Suction nozzle 60 communicates with a positive and negative pressure supply device (not shown) through positive pressure air and negative pressure air passages. Suction nozzle 60 picks up and holds the electronic component by using a negative pressure, and separates the held electronic component by using a positive pressure. Mounting head 32 includes a nozzle lifting and lowering device (not shown) that lifts and lowers suction nozzle 60. Mounting head 32 changes a position of the held electronic component in an up-down direction with the nozzle lifting and lowering device.

Moving device 34 is a device that moves mounting head 32 to any position on base 52. Specifically, moving device 34 includes X-direction slide mechanism 70 and Y-direction slide mechanism 72. Y-direction slide mechanism 72 is disposed on beam 73 suspended on base 52, and has Y-direction slider 76 that slides in the Y direction. Y-direction slider 76 is moved to any position in the Y direction by driving of an electromagnetic motor (not shown). X-direction slide mechanism 70 has X-direction slider 80, and X-direction slider 80 is held by Y-direction slider 76 so as to be slidable in the X direction. X-direction slider 80 is moved to any position in the X direction by driving of an electromagnetic motor (not shown). Mounting head 32 is mounted on X-direction slider 80. With such a structure, mounting head 32 is moved to any position on base 52 by moving device 34.

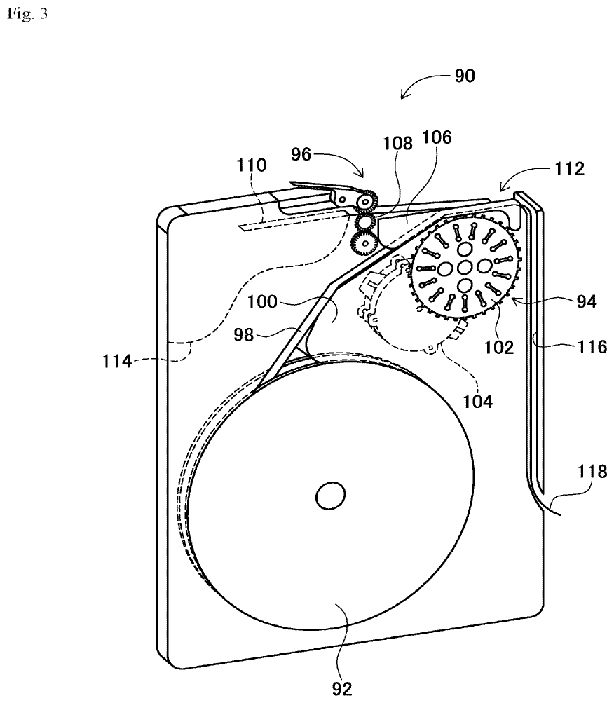

Supply device 36 is disposed at an end portion on a front side of base 52, and includes multiple tape feeders 90. As shown in FIG. 3, each tape feeder 90 includes reel 92, feed-out device 94, and peeling device 96, and supplies the electronic component at an end portion of an upper surface thereof. Specifically, taped component 98 is wound on reel 92, and taped component 98 is pulled out from reel 92 onto tape guide 100. Taped component 98 is a taped electronic component, and is formed with feed holes (not shown) at predetermined pitches. Sprocket 102 of feed-out device 94 meshes with the feed holes. Sprocket 102 is rotated by electromagnetic motor 104. With such a structure, taped component 98 is fed out toward a supply position.

In addition, peeling device 96 includes film peeling mechanism 106 and gear mechanism 108. Film peeling mechanism 106 is a mechanism for peeling off top film 110 from taped component 98, and is disposed in front of opening 112 formed at the end portion of the upper surface of tape feeder 90. Gear mechanism 108 is a mechanism that pulls top film 110 peeled off from taped component 98 into film recovery section 114. With such a structure, top film 110 is peeled off from taped component 98, so that the electronic component accommodated in taped component 98 is exposed at opening 112, and the exposed electronic component is picked up and held by suction nozzle 60 of mounting head 32. That is, opening 112 is an electronic component supply position of tape feeder 90. Tape guide passage 116 is formed on a side surface of opening 112 in a feed-out direction of taped component 98 to be directed downward. Waste tape 118 obtained by extracting the electronic component from taped component 98 is discharged through tape guide passage 116.

As shown in FIG. 2, tape feeder 90 is detachable from tape feeder holding stand 120 fixedly provided at the end portion on the front side of base 52. Multiple rails (not shown) extending in the Y direction are formed side by side in the X direction on tape feeder holding stand 120, and tape feeder 90 is detachably mounted on each rail.

Storage case 140 is disposed below tape feeder holding stand 120. As in tape feeder holding stand 120, multiple rails (not shown) extending in the Y direction are formed side by side in the X direction in storage case 140, and tape feeder 90 is detachably mounted on each rail.

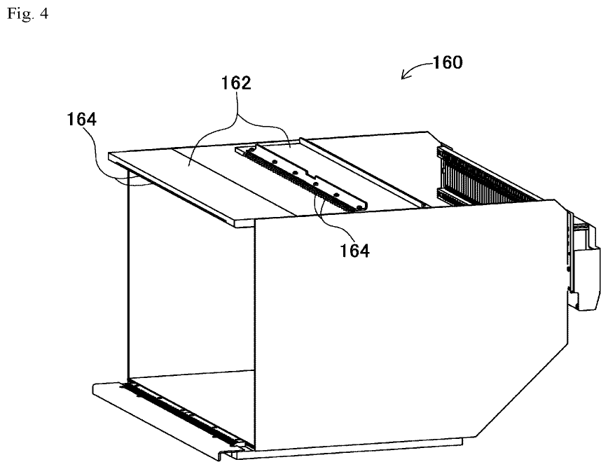

As shown in FIG. 1, storage space 150 is formed in feeder storage 20 at the same height as tape feeder holding stand 120 of mounting device 22. Storage space 150 is a space for storing storage rack 160. As shown in FIG. 4, storage rack 160 has a box shape in which a front surface is open. A height dimension of an interior of storage rack 160 having the box shape is slightly larger than a height dimension of tape feeder 90, and a depth dimension of the interior of storage rack 160 is slightly larger than a depth dimension of tape feeder 90. A width dimension of the interior of storage rack 160 is larger than N times (for example, 30 times) a width dimension of tape feeder 90. N tape feeders 90 can be stored side by side in storage rack 160 having such a shape. Multiple (N) rails 164 are formed at a lower surface of top plate 162 of storage rack 160 to extend in a front-rear direction. Therefore, by fitting an upper end of tape feeder 90 into rail 164 and pushing tape feeder 90 into storage rack 160, tape feeder 90 is stored in a state in which tape feeder 90 is positioned inside storage rack 160.

An inner dimension in a depth direction of storage space 150 is slightly larger than an outer dimension in a depth direction of storage rack 160, and an inner dimension in a width direction of storage space 150, that is, an inner dimension in the X direction is slightly larger than twice an outer dimension in a width direction of storage rack 160. An upper side of storage space 150 is open. Therefore, as shown in FIG. 1, two storage racks 160 can be stored in storage space 150 side by side in the X direction.

Further, feeder exchange device 26 performs work of exchanging tape feeder 90 on feeder storage 20 and each of five mounting devices 22. Specifically, upper guide rail 170 and lower guide rail 172 are disposed to extend in the X direction on front surfaces of feeder storage 20 and five mounting devices 22. Feeder exchange device 26 is held by upper guide rail 170 and lower guide rail 172 so as to be slidable in the X direction, and is moved to any position in the X direction by driving of an electromagnetic motor (not shown).

As shown in FIG. 2, feeder exchange device 26 includes lifting and lowering device 180, horizontal moving device 182, and clamp mechanism 184. Lifting and lowering device 180 includes pair of Z-direction guide rails 186, and pair of Z-direction guide rails 186 are disposed to extend in the Z direction on the front side of tape feeder holding stand 120 and storage case 140 of mounting device 22. In addition, horizontal moving device 182 includes X-direction guide rail 188, and X-direction guide rail 188 is held by pair of Z-direction guide rails 186 to extend in the X direction. X-direction guide rail 188 moves to any position in the Z direction by driving of a Z-direction motor (not shown). In addition, X-direction guide rail 188 holds clamp mechanism 184 to be movable along an axis of X-direction guide rail 188. Clamp mechanism 184 moves to any position in the X direction by driving of an X-direction motor (not shown). Further, clamp mechanism 184 can expand and contract in the Y direction, and expands and contracts in the Y direction by driving of an expansion and contraction motor (not shown). In addition, clamper 190 that clamps tape feeder 90 is provided at a distal end portion of clamp mechanism 184. With such a structure, feeder exchange device 26 automatically exchanges tape feeder 90 between tape feeder holding stand 120, storage case 140, and storage rack 160.

With the above-described configuration, in board work system 10, circuit board 57 is conveyed by conveyance device 30 inside five mounting devices 22, and the electronic components are mounted on circuit board 57 by mounting device 22. Specifically, first, circuit board 57 is loaded into the mounting device 22 disposed at the most upstream position among five mounting devices 22. Then, in the mounting device 22, circuit board 57 is conveyed to a work position, and is fixedly held at the position. Tape feeder 90 mounted on tape feeder holding stand 120 feeds out taped component 98 and supplies the electronic component at the supply position. Then, mounting head 32 moves to a position above the supply position of the electronic component, and picks up and holds the electronic component by using suction nozzle 60. Subsequently, mounting head 32 moves to a position above circuit board 57, and mounts the held electronic component on the circuit board 57. When the work of mounting the electronic component on the circuit board 57 ends, the circuit board 57 is conveyed downstream and is loaded into the mounting device 22 disposed on the downstream side. The above-described mounting work is subsequently executed by each mounting device 22, so that the circuit board 57 on which the electronic components are mounted is produced.

In this manner, mounting devices 22 are configured to pick up and hold the electronic components supplied by tape feeder 90 by using suction nozzle 60 of mounting head 32, and mount the picked up and held electronic components on the circuit board 57. In mounting devices 22 configured as described above, for example, tape feeder 90 mounted on tape feeder holding stand 120 is exchanged by feeder exchange device 26 in order to respond replenishment, setup change, and the like of electronic components. That is, tape feeder 90 that is an exchange target is removed from tape feeder holding stand 120 by clamp mechanism 184 of feeder exchange device 26. Then, removed tape feeder 90 is stored in an empty slot of storage case 140 or storage rack 160. Subsequently, the tape feeder 90 scheduled to be mounted on tape feeder holding stand 120 is clamped by clamp mechanism 184 of feeder exchange device 26 from storage case 140 or storage rack 160. Then, tape feeder 90 clamped by clamp mechanism 184 is mounted on tape feeder holding stand 120.

In addition, storage case 140 basically stores tape feeder 90 that accommodates an electronic component necessary for the mounting work performed by mounting device 22. Therefore, tape feeder 90 is exchanged between tape feeder holding stand 120 and storage case 140 when replenishing the electronic component during the mounting work. Meanwhile, storage rack 160 of feeder storage 20 basically stores tape feeder 90 that accommodates the electronic component necessary for mounting work (hereinafter, referred to as “next mounting work”) subsequent to the mounting work performed by mounting device 22. Therefore, during setup work of the next mounting work, tape feeder 90 is exchanged between tape feeder holding stand 120 of mounting device 22 and storage rack 160 of feeder storage 20, or between storage case 140 of mounting device 22 and storage rack 160 of feeder storage 20.

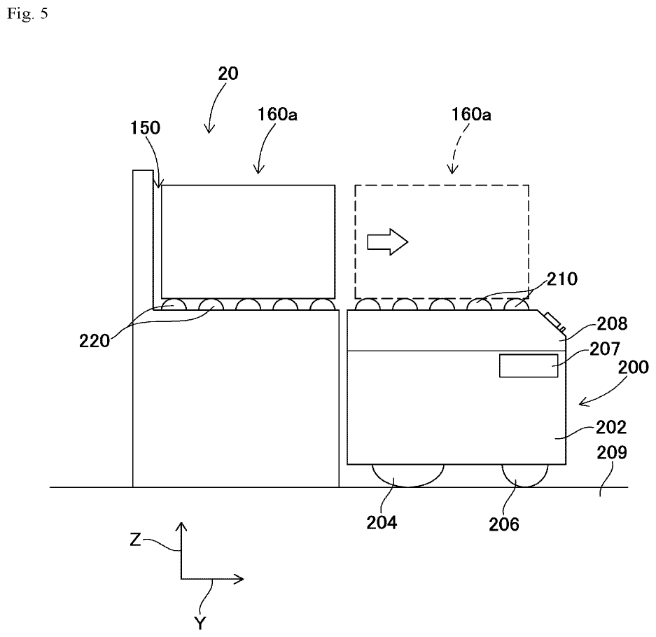

In feeder storage 20, storage rack 160 is automatically exchanged by automatic conveyance cart 200 shown in FIG. 5. Specifically, automatic conveyance cart 200 includes pair of drive wheels (only one of the pair of drive wheels is shown) 204 and pair of steerable wheels (only one of the pair of steerable wheels is shown) 206 disposed at a lower surface of housing 202. Operations of drive wheels 204 and steerable wheels 206 are controlled by control device 207. As a result, automatic conveyance cart 200 can automatically move to any position under the control of control device 207 on floor 209 on which board work system 10 is disposed. Top plate 208 is disposed at an upper surface of housing 202, and multiple conveyance rollers 210 are arranged on an upper surface of top plate 208 side by side in the front-rear direction in a posture extending in a left-right direction. Each of multiple conveyance rollers 210 is rotatable about an axis extending in the left-right direction. Multiple conveyance rollers 210 rotate in either direction by driving of an electromagnetic motor (not shown).

At a lower surface of storage space 150 of feeder storage 20, multiple conveyance rollers 220 are arranged side by side in the Y direction in a posture extending in the X direction. Each of multiple conveyance rollers 220 is rotatable about an axis extending in the X direction. Multiple conveyance rollers 220 rotate in either direction by driving of an electromagnetic motor (not shown). An upper end position of conveyance roller 220 of feeder storage 20 and an upper end position of conveyance roller 210 of automatic conveyance cart 200 are substantially the same height.

With such a structure, in feeder storage 20, for example, storage rack 160 stored in storage space 150 is automatically transferred to automatic conveyance cart 200. Specifically, automatic conveyance cart 200 moves to a position facing storage space 150, in which a storage rack (hereinafter, referred to as “unnecessary rack 160a”) is accommodated, by operations of drive wheels 204 and steerable wheels 206. Then, multiple conveyance rollers 220 of feeder storage 20 rotate in a direction in which unnecessary rack 160a is discharged, and multiple conveyance rollers 210 of automatic conveyance cart 200 rotate in a direction in which unnecessary rack 160a is loaded. Accordingly, unnecessary rack 160a stored in storage space 150 is automatically transferred to automatic conveyance cart 200.

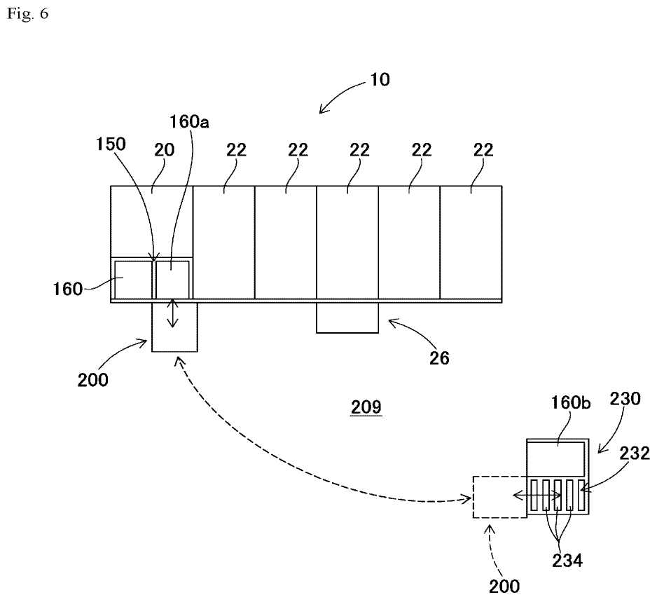

As shown in FIG. 6, rack management device 230 is also installed on floor 209 on which board work system 10 is installed. Rack management device 230 is a device that manages storage rack 160, and includes storage space 232 similarly to feeder storage 20, and can store two storage racks 160 side by side in storage space 232. In rack management device 230 shown in FIG. 6, one storage rack (hereinafter, referred to as “necessary rack 160b”) is stored. Necessary rack 160b stores tape feeder 90 for supplying the electronic component scheduled to be mounted in the next mounting work in mounting device 22. An empty space is provided next to necessary rack 160b. Similarly to storage space 150 of feeder storage 20, multiple conveyance rollers 234 are also disposed at a lower surface of storage space 232 of rack management device 230, and multiple conveyance rollers 234 also rotate in either direction by driving of an electromagnetic motor (not shown).

When unnecessary rack 160a is transferred from feeder storage 20 to automatic conveyance cart 200, automatic conveyance cart 200 moves to a position facing the empty space of rack management device 230. Then, multiple conveyance rollers 210 of automatic conveyance cart 200 rotate in a direction in which unnecessary rack 160a is discharged, and multiple conveyance rollers 234 of rack management device 230 rotate in a direction in which unnecessary rack 160a is loaded. Accordingly, unnecessary rack 160a placed on automatic conveyance cart 200 is automatically transferred to storage space 232 of rack management device 230. Subsequently, automatic conveyance cart 200 moves to a position facing necessary rack 160b stored in storage space 232 of rack management device 230. Then, multiple conveyance rollers 234 of rack management device 230 rotate in a direction in which necessary rack 160b is discharged, and multiple conveyance rollers 210 of automatic conveyance cart 200 rotate in a direction in which necessary rack 160b is loaded. Accordingly, necessary rack 160b accommodated in rack management device 230 is automatically transferred to automatic conveyance cart 200.

Next, automatic conveyance cart 200 to which necessary rack 160b is transferred moves to an empty space of feeder storage 20, that is, a position facing a space in which unnecessary rack 160a was placed. Then, multiple conveyance rollers 210 of automatic conveyance cart 200 rotate in a direction in which necessary rack 160b is discharged, and multiple conveyance rollers 220 of feeder storage 20 rotate in a direction in which necessary rack 160b is loaded. Accordingly, necessary rack 160b placed on automatic conveyance cart 200 is automatically transferred to storage space 150 of feeder storage 20.

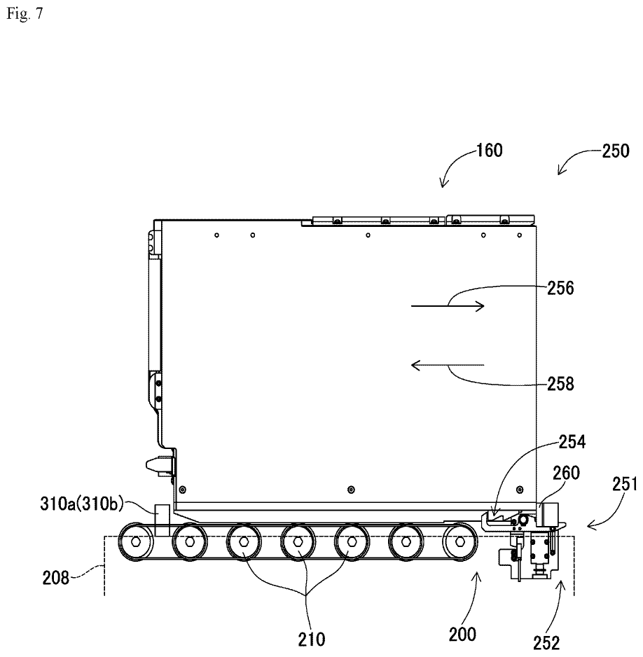

In this way, unnecessary rack 160a stored in feeder storage 20 is automatically exchanged for necessary rack 160b by automatic conveyance cart 200. When automatic conveyance cart 200 moves between feeder storage 20 and rack management device 230, there is a concern that storage rack 160 placed on an upper surface of automatic conveyance cart 200 falls off automatic conveyance cart 200. In particular, multiple conveyance rollers 210 are disposed on the upper surface of automatic conveyance cart 200, and storage rack 160 placed on multiple conveyance rollers 210 slides in a predetermined direction, that is, a direction in which multiple conveyance rollers 210 are arranged. That is, storage rack 160 is disposed on the upper surface of automatic conveyance cart 200 so as to be slidable in the direction in which multiple conveyance rollers 210 are arranged. Therefore, when automatic conveyance cart 200 moves, there is a concern that storage rack 160 placed on the upper surface of automatic conveyance cart 200 falls off automatic conveyance cart 200. In view of the above, as shown in FIG. 7, lock mechanism 251 is disposed in automatic conveyance cart 200 and storage rack 160, that is, in conveyance device 250 including automatic conveyance cart 200 and storage rack 160.

Specifically, lock mechanism 251 includes latching mechanism 252 disposed at top plate 208 of automatic conveyance cart 200 and latched block 254 disposed at a lower surface of storage rack 160. In FIG. 7, storage rack 160 placed on the upper surface of automatic conveyance cart 200 slides in a direction of arrow 256 when being loaded onto the upper surface of automatic conveyance cart 200, and slides in a direction of arrow 258 when being discharged from the upper surface of automatic conveyance cart 200. Sliding of storage rack 160 in a loading direction (hereinafter, referred to as “rack loading direction”) (arrow 256) to automatic conveyance cart 200 is restricted by stopper 260 fixed to the upper surface of automatic conveyance cart 200. A position where the sliding is restricted by stopper 260 serves as a defined position (hereinafter, referred to as a “conveyance position”) when storage rack 160 is conveyed. Furthermore, sliding of storage rack 160 located at the conveyance position in a discharge direction (hereinafter, referred to as “rack discharge direction”) (arrow 258) from automatic conveyance cart 200 is restricted by lock mechanism 251. That is, storage rack 160 is locked at the conveyance position by lock mechanism 251. Note that, in the following description, the rack loading direction (arrow 256) and the rack discharge direction (arrow 258) may be referred to as a sliding direction of storage rack 160.

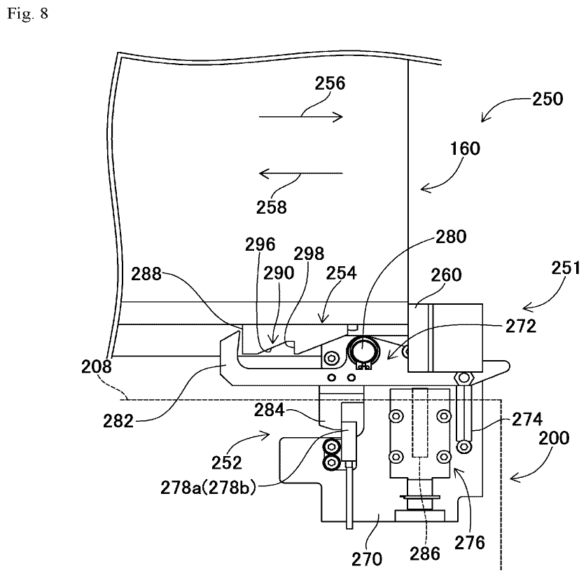

Specifically, as shown in FIG. 8, latching mechanism 252 includes base 270, latch lever 272, coil spring 274, solenoid 276, and first detection sensor 278. Base 270 is fixed to top plate 208 of automatic conveyance cart 200, and latch lever 272 is disposed at an upper end portion of base 270 in a posture extending in the sliding direction of storage rack 160. Latch lever 272 is swingably supported by support shaft 280 located at a center portion of storage rack 160 in the sliding direction. In addition, latch lever 272 has a hook shape at an end portion (hereinafter, referred to as a “front end portion”) on a side in the rack discharge direction (arrow 258), and the front end portion thereof is latching section 282 that is bent upward. A first end of coil spring 274 is connected to an end portion (hereinafter, referred to as a “rear end portion”) of latch lever 272 on an opposite side to the front end portion. Coil spring 274 is disposed in a posture extending in the up-down direction, and a second end of coil spring 274 is coupled to base 270 below latch lever 272. Coil spring 274 is an extension spring, and the rear end portion of latch lever 272 is urged downward by an elastic force of coil spring 274. Therefore, the front end portion of latch lever 272, that is, latching section 282 is urged upward by the elastic force of coil spring 274. At a lower surface of latch lever 272, protrusion portion 284 extending downward is disposed on support shaft 280 side between support shaft 280 and latching section 282.

Further, solenoid 276 is disposed in a posture extending in the up-down direction between support shaft 280 and the rear end portion of latch lever 272 below latch lever 272. When solenoid 276 is energized, plunger 286 extends upward from an upper surface of solenoid 276. Accordingly, an upper end of plunger 286 comes into contact with a portion between the rear end portion of latch lever 272 and support shaft 280, causing the rear end portion of latch lever 272 to swing upward against the elastic force of coil spring 274. At this time, the front end portion of latch lever 272, that is, latching section 282 swings downward against the elastic force of coil spring 274. To the contrary, in a state in which solenoid 276 is not energized, plunger 286 does not extend from the upper surface of solenoid 276 and is located inside solenoid 276. Therefore, the upper end of plunger 286 does not contact latch lever 272, and the rear end portion of latch lever 272 swings downward by the elastic force of coil spring 274. At this time, the front end portion of latch lever 272, that is, latching section 282 swings upward by the elastic force of coil spring 274.

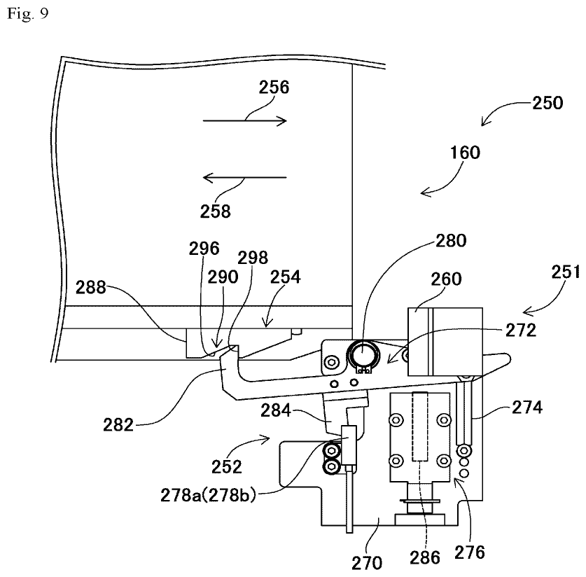

First detection sensor 278 is a photoelectric sensor and includes light emitter 278a and light receiver 278b. Light emitter 278a and light receiver 278b are disposed so as to sandwich protrusion portion 284 of latch lever 272, and light emitted from light emitter 278a is received by light receiver 278b. However, as latch lever 272 swings, the light emitted from light emitter 278a is blocked by protrusion portion 284 and is not received by light receiver 278b. That is, as shown in FIG. 8, in a state in which latching section 282 of latch lever 272 swings upward, protrusion portion 284 is not located between light emitter 278a and light receiver 278b, and the light emitted from light emitter 278a is received by light receiver 278b. To the contrary, as shown in FIG. 9, when latching section 282 of latch lever 272 swings downward, protrusion portion 284 comes between light emitter 278a and light receiver 278b, and the light emitted from light emitter 278a is blocked by protrusion portion 284 and is not received by light receiver 278b. Thus, first detection sensor 278 detects the swing of latch lever 272.

Further, latched block 254 is fixed to the lower surface of storage rack 160, and as shown in FIG. 8, when storage rack 160 is placed at the conveyance position, latched block 254 faces between latching section 282 of latch lever 272 and support shaft 280. Therefore, when storage rack 160 is placed at the conveyance position, latched block 254 is latched by latching section 282 of latch lever 272 at end surface 288 of latched block 254 on the side in the rack discharge direction (arrow 258). That is, end surface 288 of latched block 254 functions as a first latched section that is latched by latching section 282 of latch lever 272 when storage rack 160 is placed at the conveyance position.

Recessed portion 290 is formed at the lower surface of latched block 254 at a position slightly deviating from end surface 288 in the rack loading direction (arrow 256). In recessed portion 290, an inner wall surface on the side in the rack discharge direction (arrow 258) is tapered surface 296, and an inner wall surface on a side in the rack loading direction (arrow 256) is vertical surface 298. Therefore, when storage rack 160 deviates from the conveyance position in the rack discharge direction (arrow 258), as shown in FIG. 9, latched block 254 is latched by latching section 282 of latch lever 272 in recessed portion 290. That is, recessed portion 290 of latched block 254 functions as a second latched section that is latched by latching section 282 of latch lever 272 when storage rack 160 deviates from the conveyance position in the rack discharge direction (arrow 258).

As described above, in lock mechanism 251, end surface 288 of latched block 254 functioning as the first latched section and recessed portion 290 of latched block 254 functioning as the second latched section are formed side by side in the sliding direction of the storage rack 160. Then, latching section 282 of latch lever 272 latches onto end surface 288 of latched block 254, so that storage rack 160 is locked at the conveyance position, and when storage rack 160 deviates from the conveyance position in the rack discharge direction (arrow 258), latching section 282 of latch lever 272 latches into recessed portion 290 of latched block 254.

In addition, when latching section 282 of latch lever 272 is latched to end surface 288 of latched block 254, that is, when storage rack 160 is placed at the conveyance position, as shown in FIG. 8, protrusion portion 284 of latch lever 272 is not located between light emitter 278a and light receiver 278b of first detection sensor 278. Therefore, the light emitted from light emitter 278a is received by light receiver 278b. To the contrary, when latching section 282 of latch lever 272 is latched into recessed portion 290 of latched block 254, that is, when storage rack 160 deviates from the conveyance position, as shown in FIG. 9, protrusion portion 284 of latch lever 272 comes between light emitter 278a and light receiver 278b of first detection sensor 278. Therefore, the light emitted from light emitter 278a is blocked by protrusion portion 284 and is not received by light receiver 278b. In this way, first detection sensor 278 can detect whether latching section 282 of latch lever 272 is latched to end surface 288 or recessed portion 290 of latched block 254, that is, whether latching section 282 of latch lever 272 is latched to end surface 288 of latched block 254. Further, if latching section 282 of latch lever 272 is latched to end surface 288 of latched block 254, storage rack 160 is placed at the conveyance position, and if latching section 282 of latch lever 272 is latched to recessed portion 290 of latched block 254, storage rack 160 deviates from the conveyance position. Therefore, it can be said that first detection sensor 278 can detect whether storage rack 160 deviates from the conveyance position, that is, the deviation of storage rack 160 from the conveyance position.

With such a structure, in conveyance device 250, storage rack 160 is locked by lock mechanism 251 when storage rack 160 is placed at the conveyance position, and the movement of automatic conveyance cart 200 is stopped when storage rack 160 deviates from the conveyance position. Specifically, when storage rack 160 is placed at the conveyance position, latching section 282 of latch lever 272 is urged upward by the elastic force of coil spring 274 and latched onto end surface 288 of latched block 254, so that storage rack 160 is locked. At this time, first detection sensor 278 detects that light receiver 278b is receiving light. First detection sensor 278 is connected to control device 207, and when first detection sensor 278 detects that light receiver 278b is receiving light, first detection sensor 278 outputs an ON signal to control device 207.

However, latching section 282 of latch lever 272 may come off end surface 288 of latched block 254 due to vibration during movement of automatic conveyance cart 200. In such a case, as shown in FIG. 9, storage rack 160 deviates from the conveyance position, and latching section 282 of latch lever 272 latches into recessed portion 290 of latched block 254. At this time, first detection sensor 278 detects that light receiver 278b is not receiving light, and outputs an OFF signal to control device 207. Upon receiving the OFF signal from first detection sensor 278, control device 207 determines whether the OFF signal is continuously received for a set time (for example, 0.1 seconds). At this time, when the OFF signal is continuously received for the set time, control device 207 outputs a stop command as error information to drive wheels 204 and steerable wheels 206. Then, drive wheels 204 and steerable wheels 206 stop the movement of automatic conveyance cart 200 in response to the stop command. Accordingly, when storage rack 160 deviates from the conveyance position, it is possible to prevent storage rack 160 from falling off automatic conveyance cart 200.

When the OFF signal is not continuously received for the set time, that is, when the OFF signal is continuously received for less than the set time, control device 207 does not output the stop command to drive wheels 204 and steerable wheels 206. This is because there are cases in which latching section 282 of latch lever 272 swings downward due to vibration during the movement of automatic conveyance cart 200, but does not come off end surface 288 of latched block 254. There are also cases in which latching section 282 of latch lever 272 swings downward and once comes off end surface 288 of latched block 254, but may latch onto end surface 288 again. That is, if the stop command is output each time the OFF signal is received, there is a possibility that the movement of automatic conveyance cart 200 is stopped even though latching section 282 of latch lever 272 has not come off end surface 288 of latched block 254. Accordingly, it is possible to stop the movement of automatic conveyance cart 200 only when latching section 282 comes off end surface 288 and storage rack 160 deviates from the conveyance position. When the OFF signal is continuously received for the set time, control device 207 outputs a generation command as error information not only to drive wheels 204 and steerable wheels 206 but also to a speaker (not shown) built into automatic conveyance cart 200. The speaker generates a buzzer sound or the like in response to the generation command. Accordingly, a worker can recognize an abnormality in automatic conveyance cart 200.

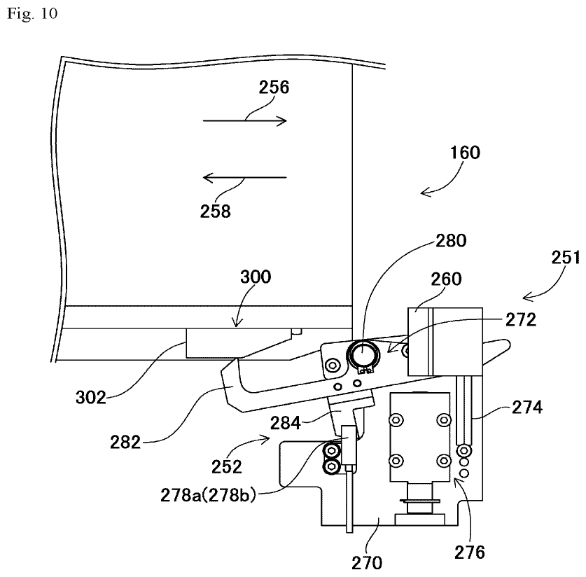

In addition, in lock mechanism 251, when latching section 282 of latch lever 272 comes off end surface 288 of latched block 254 and storage rack 160 deviates from the conveyance position, not only is the movement of automatic conveyance cart 200 stopped, but also latching section 282 of latch lever 272 latches into recessed portion 290 of latched block 254. Accordingly, storage rack 160 can be locked again by lock mechanism 251, thereby reliably preventing storage rack 160 from falling off automatic conveyance cart 200. For example, as shown in FIG. 10, a case in which latched block 300 in which recessed portion 290 is not formed is disposed in storage rack 160 will be considered. In such a case, when latching section 282 of latch lever 272 comes off end surface 302 of latched block 300 and storage rack 160 deviates from the conveyance position, first detection sensor 278 outputs an OFF signal, thereby stopping the movement of automatic conveyance cart 200. However, latching section 282 of latch lever 272 that has come off end surface 302 of latched block 300 only comes into contact with a lower surface of latched block 300, and does not latch to any part of latched block 300. As described above, when automatic conveyance cart 200 stops on an inclined surface in a state in which latch lever 272 is not latched to any part of latched block 300, there is a concern that storage rack 160 slides on conveyance rollers 210 of automatic conveyance cart 200 and fall off automatic conveyance cart 200 due to a weight of storage rack 160. Even when automatic conveyance cart 200 stops on a flat surface, there is a concern that storage rack 160 slides on conveyance rollers 210 of automatic conveyance cart 200 and fall off automatic conveyance cart 200 due to an inertia of storage rack 160 when automatic conveyance cart 200 is brought to a stop. In view of this, in latched block 254, recessed portion 290 is formed alongside end surface 288 of latched block 254 in the sliding direction of storage rack 160. Accordingly, latching section 282 of latch lever 272, which has come off end surface 288 of latched block 254, latches into recessed portion 290, allowing storage rack 160 can be locked again by lock mechanism 251, thereby reliably preventing storage rack 160 from falling off automatic conveyance cart 200. In particular, since latching section 282 of latch lever 272 latches onto vertical surface 298 of recessed portion 290, it is possible to effectively prevent storage rack 160 from sliding in the rack discharge direction (arrow 258). Meanwhile, when storage rack 160 is loaded onto automatic conveyance cart 200 by an operation of conveyance rollers 210, latching section 282 of latch lever 272 comes into sliding contact with tapered surface 296 of recessed portion 290, thereby ensuring smooth loading of storage rack 160.

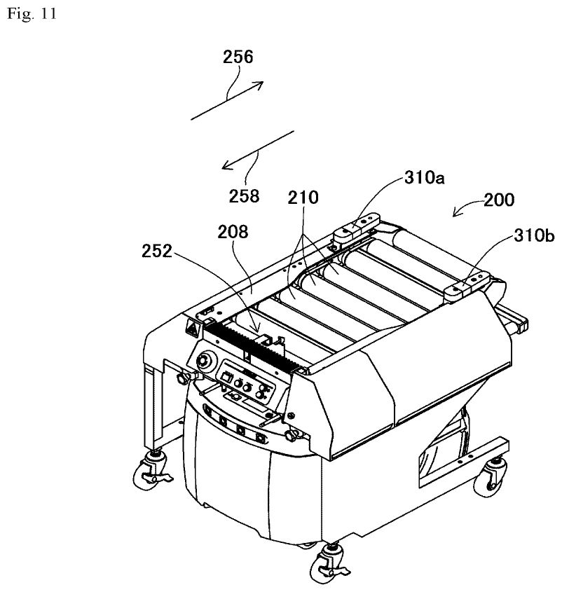

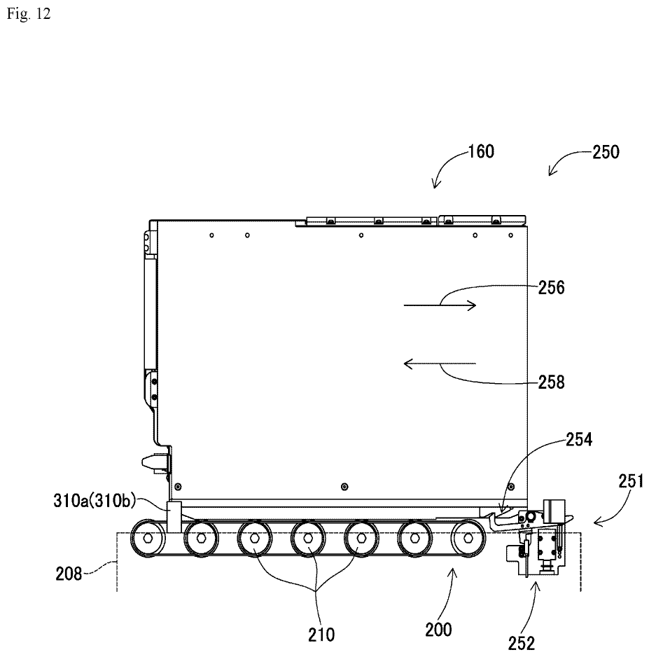

In addition, conveyance device 250 is also provided with second detection sensor (see FIG. 11) 310, which is different from first detection sensor 278, as a sensor for detecting deviation of storage rack 160 from the conveyance position, and the movement of automatic conveyance cart 200 is stopped according to a detection value of second detection sensor 310. Specifically, second detection sensor 310 is also a photoelectric sensor, and includes light emitter 310a and light receiver 310b as shown in FIG. 11. Light emitter 310a and light receiver 310b are disposed so as to sandwich an upper side of conveyance rollers 210 at an end portion of top plate 208 of automatic conveyance cart 200 opposite to an end portion on a side where latching mechanism 252 is disposed, that is, at an end portion on the side in the rack discharge direction (arrow 258). Then, light emitted from light emitter 310a is received by light receiver 310b. Therefore, when storage rack 160 is being loaded and discharged by conveyance rollers 210, the light emitted from light emitter 310a is blocked by storage rack 160 and is not received by light receiver 278b. However, as shown in FIG. 7, when storage rack 160 is placed at the conveyance position, that is, when latching section 282 of latch lever 272 is latched onto end surface 288 of latched block 254, the light emitted from light emitter 310a is not blocked by storage rack 160 and is received by light receiver 278b. To the contrary, as shown in FIG. 12, when storage rack 160 deviates from the conveyance position, that is, when latching section 282 of latch lever 272 is latched into recessed portion 290 of latched block 254, the light emitted from light emitter 310a is blocked by storage rack 160 and is not received by light receiver 278b. Accordingly, second detection sensor 310 can detect whether storage rack 160 deviates from the conveyance position, that is, the deviation of storage rack 160 from the conveyance position by detecting the position of storage rack 160 relative to automatic conveyance cart 200.

With such a structure, in conveyance device 250, the movement of automatic conveyance cart 200 is stopped according to the detection value of not only first detection sensor 278 but also second detection sensor 310. Specifically, when storage rack 160 is placed at the conveyance position, storage rack 160 is locked by latching section 282 of latch lever 272 being latched to end surface 288 of latched block 254. At this time, second detection sensor 310 detects that light receiver 310b is receiving light and outputs an ON signal to control device 207.

Then, when latching section 282 of latch lever 272 comes off end surface 288 of latched block 254 due to vibration or the like during movement of automatic conveyance cart 200, storage rack 160 deviates from the conveyance position, and latching section 282 of latch lever 272 latches into recessed portion 290 of latched block 254. At this time, second detection sensor 310 detects that light receiver 310b is not receiving light, and outputs an OFF signal to control device 207. Upon receiving the OFF signal from second detection sensor 310, control device 207 outputs a stop command as error information to drive wheels 204 and steerable wheels 206. That is, when the OFF signal is received from first detection sensor 278, control device 207 outputs the error information on the condition that the reception of the OFF signal continues for the set time. However, when the OFF signal is received from second detection sensor 310, control device 207 outputs the error information without requiring that the reception of the OFF signal continues for the set time. This is because second detection sensor 310 detects the position of storage rack 160 relative to automatic conveyance cart 200, and when a positional deviation is detected by second detection sensor 310, latching section 282 of latch lever 272 comes off end surface 288 of latched block 254. Then, drive wheels 204 and steerable wheels 206 stop the movement of automatic conveyance cart 200 in response to the stop command. Accordingly, when storage rack 160 deviates from the conveyance position, it is possible to prevent storage rack 160 from falling off automatic conveyance cart 200. Control device 207 outputs a generation command as error information not only to drive wheels 204 and steerable wheels 206 but also to a speaker built into automatic conveyance cart 200, and the speaker generates a buzzer sound or the like in response to the generation command. As described above, in conveyance device 250, two sensors, first detection sensor 278 and second detection sensor 310 are disposed, and when deviation of storage rack 160 from the conveyance position is detected by at least one of the two sensors, automatic conveyance cart 200 stops and a buzzer sound is generated. Accordingly, it is possible to reliably detect the deviation of storage rack 160 from the conveyance position, stop automatic conveyance cart 200, and generate a buzzer sound.

It should be noted that, in the above embodiment, storage rack 160 is an example of a conveyed body. Automatic conveyance cart 200 is an example of a cart. Control device 207 is an example of an output device. Conveyance device 250 is an example of a conveyance device. First detection sensor 278 is an example of a sensor. Latching section 282 is an example of a latching section. End surface 288 is an example of a first latched section. Recessed portion 290 is an example of a latched section other than the first latched section. Second detection sensor 310 is an example of the sensor.

The present embodiment, which has been described heretofore, provides the following effects.

End surface 288 and recessed portion 290 are formed in latched block 254 side by side in the sliding direction of storage rack 160. Storage rack 160 is placed at the conveyance position of automatic conveyance cart 200 by latching section 282 of latch lever 272 being latched to end surface 288 of latched block 254, and latching section 282 of latch lever 272 latches into recessed portion 290 of latched block 254 when storage rack 160 deviates from the conveyance position. Accordingly, it is possible to prevent storage rack 160 from falling off automatic conveyance cart 200.

In automatic conveyance cart 200, first detection sensor 278 and second detection sensor 310 that detect deviation of storage rack 160 from the conveyance position are disposed. When at least one of first detection sensor 278 and second detection sensor 310 detects the deviation of storage rack 160 from the conveyance position, control device 207 outputs error information. Accordingly, it is possible to take measures to prevent storage rack 160 from falling.

First detection sensor 278 detects the deviation of storage rack 160 from the conveyance position by detecting whether latching section 282 of latch lever 272 is latched to end surface 288 of latched block 254. Accordingly, the deviation of storage rack 160 from the conveyance position can be appropriately detected.

Second detection sensor 310 detects deviation of storage rack 160 from the conveyance position by detecting a position of storage rack 160 relative to automatic conveyance cart 200. Accordingly, the deviation of storage rack 160 from the conveyance position can be appropriately detected.

When a stop command is output as error information by control device 207, the movement of automatic conveyance cart 200 is stopped. Accordingly, it is possible to appropriately prevent storage rack 160 from falling off automatic conveyance cart 200.

When the deviation of storage rack 160 from the conveyance position is continuously detected by first detection sensor 278 for a set time, control device 207 outputs error information. Accordingly, the error information is output only when storage rack 160 deviates from the conveyance position.

The present disclosure is not limited to the above example, but can be carried out in various forms in which various changes and improvements are made based on the knowledge of those skilled in the art. Specifically, for example, in the above example, two latched sections, end surface 288 and recessed portion 290, are formed in latched block 254 side by side in the sliding direction of storage rack 160, but three or more latched sections may be formed side by side in the sliding direction of storage rack 160.

Although latching section 282 of latch lever 272 has a hook shape, various shapes such as a projection portion, a protrusion portion, a recessed portion, and a hook shape can be adopted as long as the shape allows latching to the latched section. The latched section is not limited to end surface 288 and recessed portion 290 of latched block 254, and various shapes such as a projection portion, a protrusion portion, a recessed portion, and a hook shape can be adopted as long as the shape allows latching of the latching section.

In addition, in the above example, two sensors, first detection sensor 278 and second detection sensor 310, are disposed in automatic conveyance cart 200, but one of the two sensors may be disposed in automatic conveyance cart 200. Further, a sensor capable of detecting positional deviation of the storage rack by various methods can be adopted as long as the sensor can detect the deviation of storage rack 160 from the conveyance position.

In the above example, when an OFF signal is received from second detection sensor 310, control device 207 outputs the error information without requiring that the reception of the OFF signal continues for the set time. Alternatively, when an OFF signal is received from first detection sensor 278, control device 207 may output the error information on the condition that the reception of the OFF signal continues for the set time, as in the case where the OFF signal is received from second detection sensor 310.

In the above example, as shown in FIG. 5, a moving direction of automatic conveyance cart 200 and the direction in which multiple conveyance rollers 210 are arranged are the same. That is, the moving direction of automatic conveyance cart 200 and the sliding direction of storage rack 160 are the same, and a direction in which multiple latched sections are arranged is the same as the moving direction of automatic conveyance cart 200. Alternatively, the moving direction of automatic conveyance cart 200 and the sliding direction of storage rack 160 may be different from each other, and the direction in which the multiple latched sections are arranged may be different from the moving direction of automatic conveyance cart 200.

In the above-described example, storage rack 160 that stores tape feeder 90 is conveyed by automatic conveyance cart 200, but the configuration is not limited to storage rack 160, and various members may be conveyed by automatic conveyance cart 200. Specifically, for example, a tray magazine that stores a tray for placing a component, a mask magazine that stores a mask used for solder printing, a board magazine that stores a board, and the like may be further conveyed by automatic conveyance cart 200. Further, the configuration is not limited to a tool used for the mounting work, and various conveyed bodies may be conveyed by automatic conveyance cart 200.

Furthermore, in the above example, the present disclosure is applied to automatic conveyance cart 200 that automatically moves, but the present disclosure may be applied to a cart that is manually moved by a worker.

### REFERENCE SIGNS LIST

160: storage rack (conveyed body), 200: automatic conveyance cart (cart), 207: control device (output device), 250: conveyance device, 278: first detection sensor (sensor), 282: latching section, 288: end surface (first latched section), 290: recessed portion (latched section other than first latched section), 310: second detection sensor

1. A conveyance device comprising:
a cart having a latching section; and
a conveyed body configured to be placed on the cart so as to be slidable in a predetermined direction and be conveyed by movement of the cart,
wherein multiple latched sections to be latched by the latching section are formed in the conveyed body side by side in the predetermined direction, and
the conveyed body is placed at a predetermined position on the cart by the latching section latching to a first latched section among the multiple latched sections, and the latching section latches to a latched section other than the first latched section among the multiple latched sections when the conveyed body deviates from the predetermined position.

2. The conveyance device according to claim 1,
wherein the cart includes
a sensor configured to detect deviation of the conveyed body from the predetermined position, and
an output device configured to output error information when the deviation of the conveyed body from the predetermined position is detected by the sensor.

3. The conveyance device according to claim 2, wherein the sensor detects the deviation of the conveyed body from the predetermined position by detecting a position of the conveyed body relative to the cart.

4. The conveyance device according to claim 2, wherein the sensor detects the deviation of the conveyed body from the predetermined position by detecting whether the latching section is latched to the first latched section.

5. The conveyance device according to claim 2,
wherein the cart automatically moves, and
the movement of the cart automatically stops when the error information is output by the output device.

6. The conveyance device according to claim 2,
wherein the output device outputs the error information when the sensor continuously detects the deviation of the conveyed body from the predetermined position for a set time.

7. A conveyed body configured to be placed on a cart so as to be slidable in a predetermined direction and be conveyed by movement of the cart, the conveyed body comprising:
multiple latched sections to be latched by a latching section disposed on the cart, the multiple latched sections being formed in the conveyed body side by side in the predetermined direction,
wherein the conveyed body is placed at a predetermined position on the cart by the latching section latching to a first latched section among the multiple latched sections, and the latching section latches to a latched section other than the first latched section among the multiple latched sections when the conveyed body deviates from the predetermined position.
